(19) United States
(12) Patent Application Publication
(10) Pub. No.: US 2025/0357147 A1
(43) Pub. Date: Nov. 20, 2025

(54) METHOD OF MANUFACTURING SEMICONDUCTOR DEVICE

(71) Applicant: Mitsubishi Electric Corporation, Tokyo (JP)

(72) Inventors: Taketo NISHIYAMA, Tokyo (JP); Shunji MASUMORI, Tokyo (JP); Taichi OBARA, Tokyo (JP)

(73) Assignee: Mitsubishi Electric Corporation, Tokyo (JP)

(21) Appl. No.: 19/084,690

(22) Filed: Mar. 19, 2025

(30) Foreign Application Priority Data
May 16, 2024 (JP) 2024-080021

(51) Int. Cl. H01L 21/52

(52) U.S. Cl. CPC H01L 21/52

(57) ABSTRACT

A method of manufacturing the semiconductor device includes: the application step of applying the hot melt adhesive having the film thickness L1 to the upper surface of the peripheral edge portion of the insulating substrate, and then applying the thermosetting adhesive having the film thickness L2 to the periphery of the region to which the hot melt adhesive is applied on the upper surface of the peripheral edge portion of the insulating substrate; the temporary fixing step of temporarily fixing the insulating substrate and the case by fastening the case and the case fitting jig with screws; and the heating step of heating the temporarily fixed insulating substrate and the case to fix the insulating substrate and the case. L1>L2 in the temporary fixing step, and L1=L2 in the heating step.

### BACKGROUND OF THE INVENTION

### Field of the Invention

The present disclosure relates to a method of manufacturing a semiconductor device.

### Description of the Background Art

Conventionally, in a manufacturing process of a semiconductor device, a case is fixed to an insulating substrate placed on a case fitting jig with an adhesive. When the insulating substrate and the case are temporarily fixed to each other, the case and the case fitting jig are fastened to each other. However, when the case and the case fitting jig are fastened to each other, a bending force that causes warpage of the insulating substrate is applied, and a crack may be formed in the insulating layer of the insulating substrate.

In order to control warpage of an insulating substrate, a power semiconductor device has been proposed that is capable of securing a predetermined thickness of an adhesive in an adhesion step of dispersing and interposing a protruding spacer having rubber elasticity on an upper surface of a peripheral edge portion of the insulating substrate and attaching the insulating substrate to a case (see, for example, JP 2000-133769 A).

However, in the technique described in Patent Literature 1: JP 2000-133769 A, when the case is being attached, the insulating substrate may be fixed in an inclined state with respect to the bottom surface of the case due to dimensional variations of the respective members. In this case, there is a problem that the insulating substrate is cracked at the time of joining the product to the cooling member, or the thermal resistance is reduced due to insufficient contact between the product and the cooling member.

### SUMMARY

An object of the present disclosure is to provide a technique capable of preventing an insulating substrate from being fixed in an inclined state with respect to a bottom surface of a case and maintaining parallelism between the bottom surface of the case and the insulating substrate.

A method of manufacturing a semiconductor device according to the present disclosure is for manufacturing a semiconductor device including an insulating substrate and a case having a groove on a bottom surface fixed to a peripheral edge portion of the insulating substrate. The method of manufacturing a semiconductor device includes a placing step, an application step, a temporary fixing step, and a heating step. In the placing step, the insulating substrate is placed on a case fitting jig. In the application step, a hot melt adhesive having a film thickness L1 is applied to an upper surface of the peripheral edge portion of the insulating substrate, and then a thermosetting adhesive having a film thickness L2 is applied to a periphery of a region to which the hot melt adhesive is applied on the upper surface of the peripheral edge portion of the insulating substrate. In the temporary fixing step, the insulating substrate and the case are temporarily fixed by arranging the case such that the groove is positioned in the peripheral edge portion of the insulating substrate and then fastening the case and the case fitting jig with screws. In the heating step, the temporarily fixed insulating substrate and the case are heated to fix the insulating substrate and the case. L1>L2 in the temporary fixing step, and L1=L2 in the heating step.

The present disclosure can prevent an insulating substrate from being fixed in an inclined state with respect to a bottom surface of a case and maintain parallelism between the bottom surface of the case and the insulating substrate.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIGS. 1 to 4 are cross-sectional views each illustrating a method of manufacturing a semiconductor device according to a first preferred embodiment of the present disclosure;

FIG. 5 is a flowchart showing a method of manufacturing a semiconductor device according to a first preferred embodiment of the present disclosure;

FIG. 6 is a diagram showing a temperature profile of a hot melt adhesive and a thermosetting adhesive;

FIGS. 7 to 9 are cross-sectional views each illustrating a method of manufacturing a semiconductor device in a case where the film thickness L1 of the hot melt adhesive varies;

FIG. 10 is a cross-sectional view illustrating a method of manufacturing a semiconductor device according to a second preferred embodiment of the present disclosure;

FIG. 11 is a top view of the insulating substrate after the application step in the third preferred embodiment;

FIG. 12 is a top view of the insulating substrate after the application step in the fourth preferred embodiment;

FIG. 13 is a side view of the insulating substrate after the application step in the fifth preferred embodiment; and

FIGS. 14 to 17 are cross-sectional views each illustrating a method of manufacturing a semiconductor device according to a related art.

### DESCRIPTION OF THE PREFERRED EMBODIMENTS

### First Preferred Embodiment

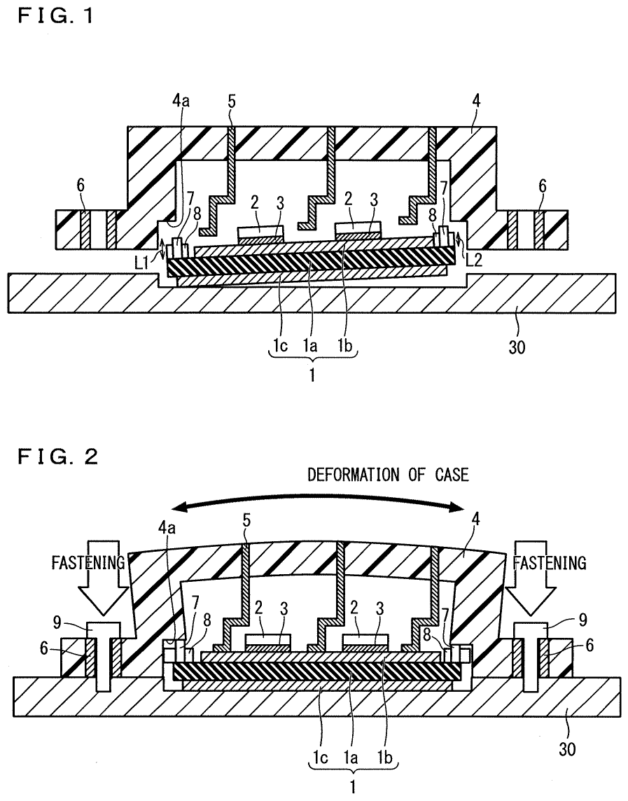

A first preferred embodiment will be described below with reference to the drawings. FIGS. 1 to 4 are cross-sectional views each illustrating a method of manufacturing a semiconductor device 100 according to a first preferred embodiment of the present disclosure.

First, the semiconductor device 100, which is a product manufactured by a manufacturing method described later, will be described. As illustrated in FIG. 4, the semiconductor device 100 is a power module, and includes an insulating substrate 1, a plurality of semiconductor elements 2, a case 4, and a plurality of terminals 5.

The insulating substrate 1 is formed in a quadrangular shape in a top view, and includes an insulating layer 1a and circuit patterns 1b and 1c. The insulating layer 1a is mainly made of, for example, ceramic. A conductive circuit pattern 1b is provided on the upper surface of the insulating layer 1a. A conductive circuit pattern 1c is provided on the lower surface of the insulating layer 1a. The circuit patterns 1b and 1c are made of, for example, copper as a main material.

The semiconductor element 2 is mounted on the upper surface of the circuit pattern 1b of the insulating substrate 1 via solder 3. The semiconductor material of the semiconductor element 2 is, for example, silicon or a wide band gap semiconductor such as silicon carbide. The semiconductor element 2 is a power semiconductor element such as an insulated gate bipolar transistor (IGBT), a metal oxide semiconductor field effect transistor (MOSFET), a free wheeling diode (FwDi), or a reverse conducting IGBT (RC-IGBT).

The case 4 is formed in a quadrangular shape in a top view, and is fixed to the upper surface of the peripheral edge portion of the insulating substrate 1 so as to enclose the plurality of semiconductor elements 2. A portion other than the peripheral edge portion of the case 4 bulges upward, and the peripheral edge portion extends to the outer peripheral side. A plurality of bushings 6 to which the screws 9 are fastened when the semiconductor device 100 is attached to a heat dissipation member (not illustrated) or a case fitting jig 30 are provided in a peripheral edge portion of the case 4. A groove 4a is provided on a bottom surface of the case 4, more specifically, on an inner peripheral side portion of the bottom surface in a peripheral edge portion of the case 4. The groove 4a is formed in the entire inner peripheral portion of the bottom surface of the peripheral edge portion of the case 4.

One end portions of the plurality of terminals 5 are joined to the circuit pattern 1b, and the other end portions of the plurality of terminals 5 are exposed from the upper surface of the case 4.

The case 4 is fixed to the insulating substrate 1 by the hot melt adhesive 7 and the thermosetting adhesive 8 applied to the upper surface of the peripheral edge portion of the insulating substrate 1, more specifically, the upper surface of the peripheral edge portion of the insulating layer 1a of the insulating substrate 1.

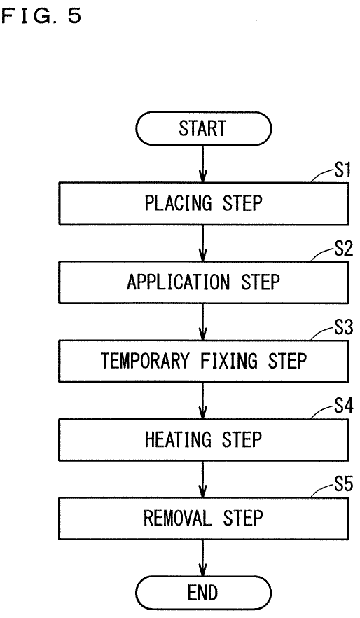

Next, a method of manufacturing the semiconductor device 100 will be described with reference to FIGS. 1 to 5. FIG. 5 is a flowchart showing a method of manufacturing a semiconductor device 100 according to a first preferred embodiment of the present disclosure.

First, as illustrated in FIG. 5, in the placing step, the insulating substrate 1 is placed on the case fitting jig 30 (step S1).

Next, in the application step, a hot melt adhesive 7 having a film thickness L1 is applied to an upper surface of the peripheral edge portion of the insulating substrate 1, and then a thermosetting adhesive 8 having a film thickness L2 is applied to a periphery of a region to which the hot melt adhesive 7 is applied on the upper surface of the peripheral edge portion of the insulating substrate 1 (step S2). At this time, L1>L2.

Next, as illustrated in FIG. 1, the case 4 is disposed such that the groove 4a is positioned in the peripheral edge portion of the insulating substrate 1. At this time, due to dimensional variations of the respective members constituting the insulating substrate 1, the insulating substrate 1 is disposed in an inclined state with respect to the upper surface of the case fitting jig 30, and is also disposed in an inclined state with respect to the bottom surface of the case 4.

Next, as illustrated in FIGS. 2 and 5, in the temporary fixing step, the case 4 is placed such that the groove 4a is positioned in the peripheral edge portion of the insulating substrate 1 while parallelism between the bottom surface of the case 4 and the insulating substrate 1 is maintained, and then the insulating substrate 1 and the case 4 are temporarily fixed by fastening the case 4 and the case fitting jig 30 with screws (step S3). At this time, a load is generated in a downward direction in the hot melt adhesive 7 due to the fastening stress, but the hot melt adhesive 7 has been cured and is maintained in its shape. Further, the portion of the case 4 bulging upward is deformed by the fastening stress.

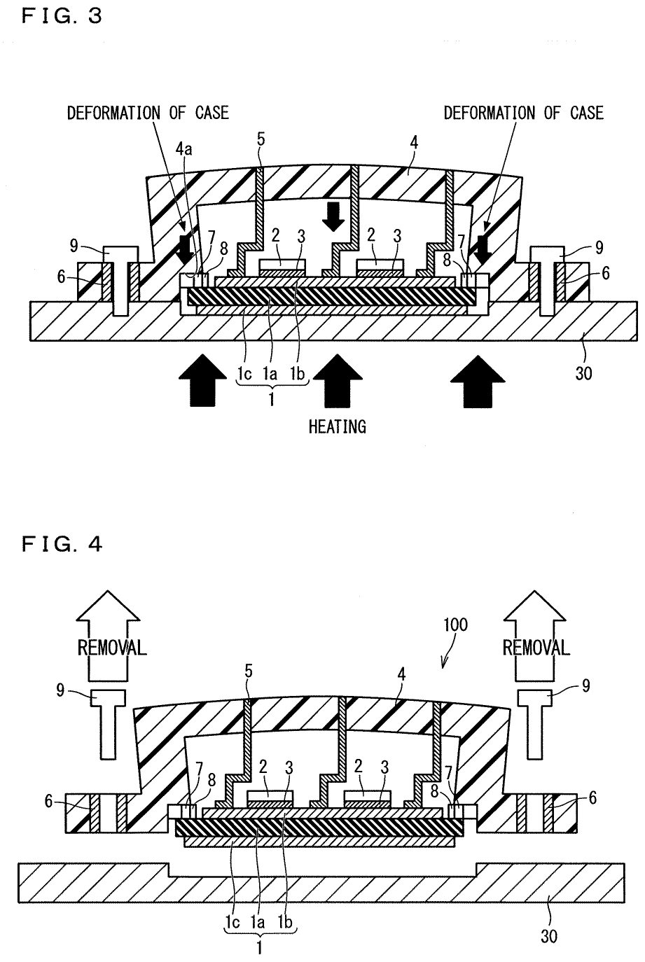

Next, as illustrated in FIGS. 3 and 5, in the heating step, the insulating substrate 1 and the case 4 that are temporarily fixed are heated to fix the insulating substrate 1 and the case 4 (step S4). In the heating step, the hot melt adhesive 7 is melted, and the film thickness L1 of the hot melt adhesive 7 is reduced by a downward load. A part of the case 4 in contact with the hot melt adhesive 7 is deformed downward, and at this time, the thermosetting adhesive 8 is cured, whereby L1=L2. As a result, parallelism between the bottom surface of the case 4 and the insulating substrate 1 can be maintained, and the insulating substrate 1 and the adhesives (the hot melt adhesive 7 and the thermosetting adhesive 8) are in uniform contact with each other, whereby it is possible to suppress concentration of fastening stress.

Next, as illustrated in FIGS. 4 and 5, a removal step of loosening the screw 9 to remove the semiconductor device 100 from the case fitting jig 30 is performed (step S5).

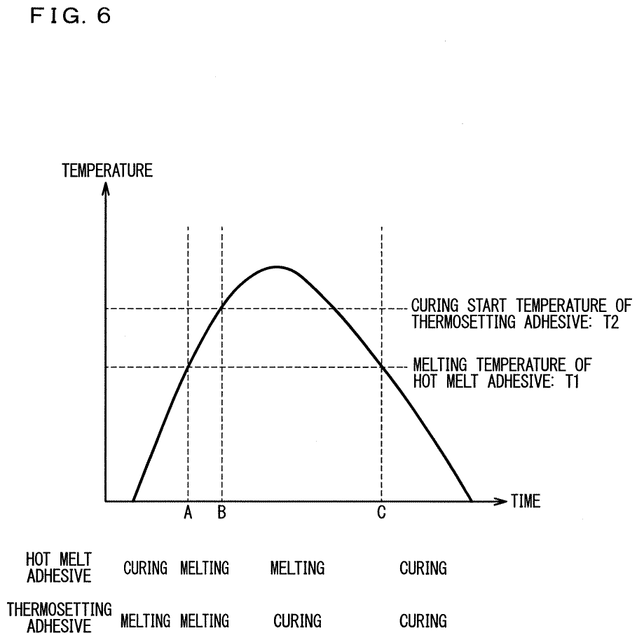

FIG. 6 is a diagram showing a temperature profile of the hot melt adhesive 7 and the thermosetting adhesive 8. In FIG. 6, before time A at which the melting temperature T1 of the hot melt adhesive 7 is reached, the hot melt adhesive 7 is cured, and the thermosetting adhesive 8 is melted. The hot melt adhesive 7 and the thermosetting adhesive 8 are melted between the time A and time B at which the curing start temperature T2 of the thermosetting adhesive 8 is reached. The hot melt adhesive 7 is melted and the thermosetting adhesive 8 is cured between the time B and time C at which the melting temperature T1 of the hot melt adhesive 7 is reached. After the time C, the hot melt adhesive 7 and the thermosetting adhesive 8 are cured.

As shown in FIG. 6, by setting the melting temperature T1 of the hot melt adhesive 7 to a temperature lower than the curing start temperature T2 of the thermosetting adhesive 8, the thermosetting adhesive 8 is cured after the hot melt adhesive 7 is melted, whereby the film thickness of the adhesive (the hot melt adhesive 7 and the thermosetting adhesive 8) is adjusted.

Next, functions and effects of the first preferred embodiment will be described in comparison with the related art. FIGS. 14 to 17 are cross-sectional views each illustrating a method of manufacturing a semiconductor device 101 according to the related art.

As illustrated in FIG. 14, in the related art, after the insulating substrate 1 is placed on the case fitting jig 30, in order to control warpage of the insulating substrate 1, a spacer 17 having rubber elasticity is dispersed and inserted into the upper surface of the peripheral edge portion of the insulating substrate 1 and an adhesive 18 is applied. The adhesive 18 is a thermosetting adhesive.

Next, the case 4 is disposed such that the groove 4a is positioned in the peripheral edge portion of the insulating substrate 1. At this time, due to dimensional variations of the respective members constituting the insulating substrate 1, the insulating substrate 1 is disposed in an inclined state with respect to the upper surface of the case fitting jig 30, and is also disposed in an inclined state with respect to the bottom surface of the case 4.

Next, as illustrated in FIG. 15, the case 4 is placed such that the groove 4a is positioned in the peripheral edge portion of the insulating substrate 1 while parallelism between the bottom surface of the case 4 and the insulating substrate 1 is maintained, and then the insulating substrate 1 and the case 4 are temporarily fixed by fastening the case 4 and the case fitting jig 30 with screws. At this time, a downward load is generated in the adhesive 18 due to the fastening stress, and the adhesive 18 is not cured and thus is deformed together with the spacer 17. Further, the portion of the case 4 bulging upward is deformed by the fastening stress.

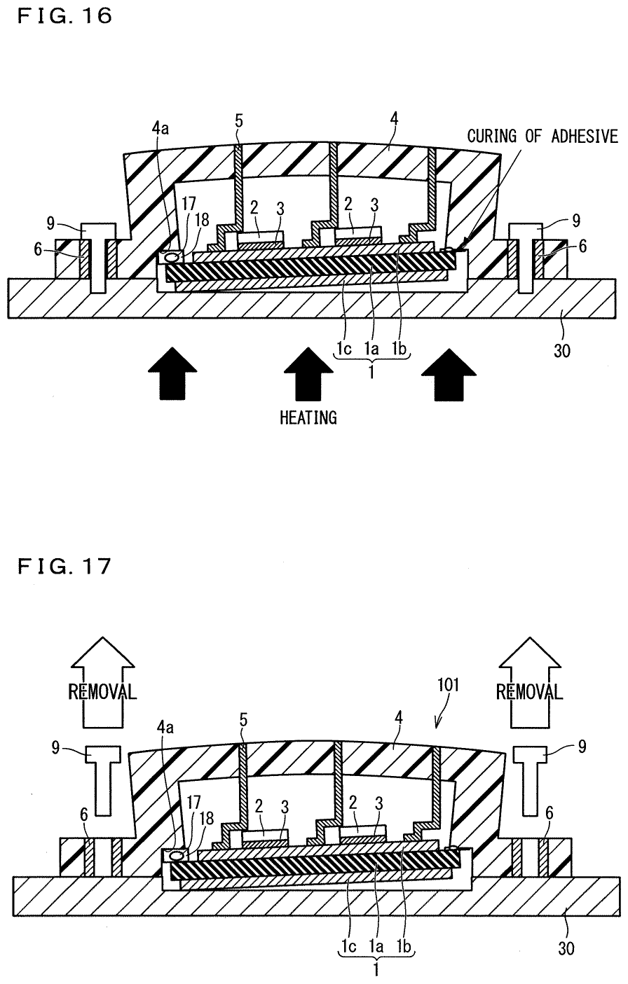

Next, as illustrated in FIG. 16, the temporarily fixed insulating substrate 1 and the case 4 are heated to fix the insulating substrate 1 and the case 4. However, since the insulating substrate 1 and the case 4 are heated in a state where the spacer 17 is deformed, the insulating substrate 1 and the case 4 are fixed in a state where the insulating substrate 1 is inclined with respect to the bottom surface of the case 4. In such a case, parallelism between the bottom surface of the case 4 and the insulating substrate 1 cannot be maintained.

On the other hand, in the first preferred embodiment, the method of manufacturing the semiconductor device 100 includes: the placing step of placing the insulating substrate 1 on the case fitting jig 30; the application step of applying the hot melt adhesive 7 having the film thickness L1 to the upper surface of the peripheral edge portion of the insulating substrate 1, and then applying the thermosetting adhesive 8 having the film thickness L2 to the periphery of the region to which the hot melt adhesive 7 is applied on the upper surface of the peripheral edge portion of the insulating substrate 1; the temporary fixing step of temporarily fixing the insulating substrate 1 and the case 4 by arranging the case 4 such that the groove 4a is positioned in the peripheral edge portion of the insulating substrate 1 and then fastening the case 4 and the case fitting jig 30 with screws; and the heating step of heating the temporarily fixed insulating substrate 1 and the case 4 to fix the insulating substrate 1 and the case 4. L1>L2 in the temporary fixing step, and L1=L2 in the heating step.

Therefore, the present disclosure can prevent the insulating substrate 1 from being fixed in an inclined state with respect to the bottom surface of the case 4 and maintain parallelism between the bottom surface of the case 4 and the insulating substrate 1. In addition, the insulating substrate 1 and the adhesives (the hot melt adhesive 7 and the thermosetting adhesive 8) are in uniform contact with each other, whereby it is possible to suppress concentration of fastening stress.

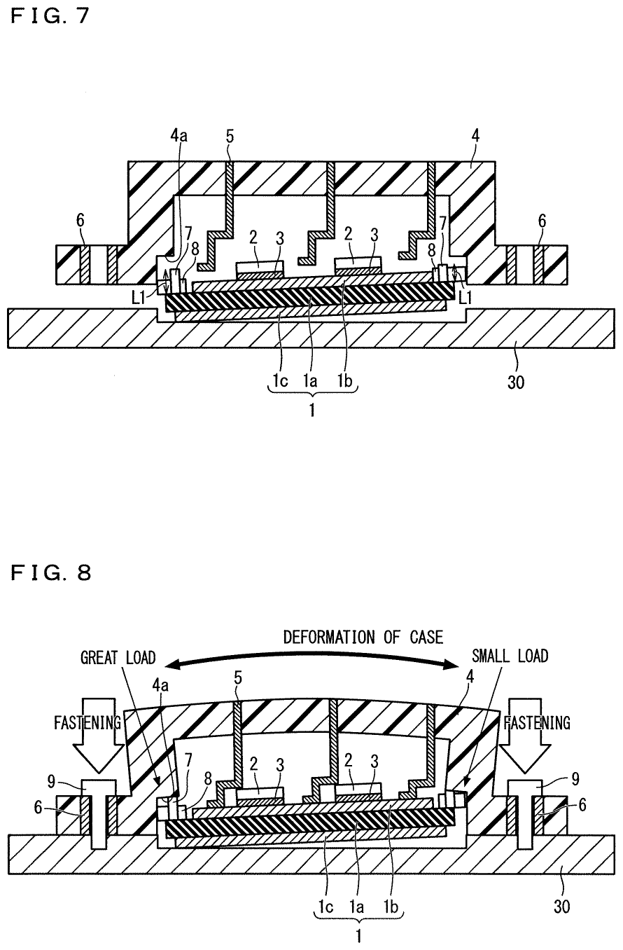

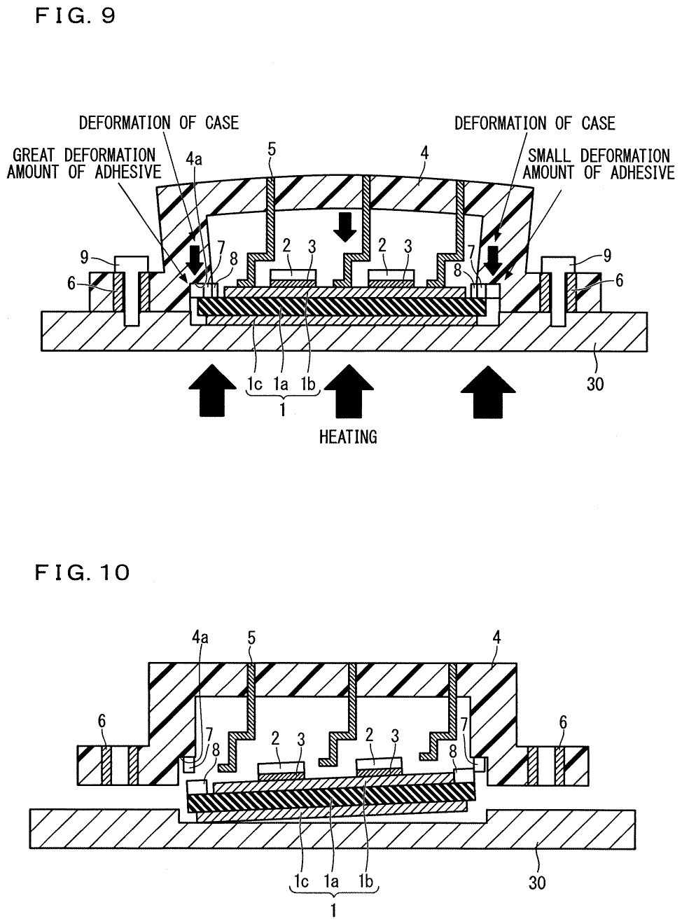

Next, a case where the film thickness L1 of the hot melt adhesive 7 varies will be briefly described. FIGS. 7 to 9 are cross-sectional views each illustrating the method of manufacturing the semiconductor device 100 in a case where the film thickness L1 of the hot melt adhesive 7 varies. Specifically, FIG. 7 corresponds to FIG. 1, FIG. 8 corresponds to FIG. 2, and FIG. 9 corresponds to FIG. 3.

As shown in FIG. 7, the film thickness L1 of the hot melt adhesive 7 is different on a left side and a right side. For example, in the following description, it is supposed that the film thickness L1 of the hot melt adhesive 7 on the left side is greater than the film thickness L1 of the hot melt adhesive 7 on the right side.

Next, as shown in FIG. 8, in the temporary fixing step, since the film thickness L1 of the hot melt adhesive 7 on the left side is greater than the film thickness L1 of the hot melt adhesive 7 on the right side, the load due to the fastening stress of the hot melt adhesive 7 on the left side is greater than that of the hot melt adhesive 7 on the right side.

Next, as shown in FIG. 9, in the heating step, the hot melt adhesive 7 is dissolved, and the film thickness L1 of the hot melt adhesive 7 is reduced by the load in the downward direction. However, since the load due to the fastening stress is greater in the hot melt adhesive 7 on the left side than in the hot melt adhesive 7 on the right side, the deformation amount of the hot melt adhesive 7 on the left side is greater than that of the hot melt adhesive 7 on the right side. That is, the hot melt adhesive 7 on the left side is shrunk more than the hot melt adhesive 7 on the right side. A part of the case 4 in contact with the hot melt adhesive 7 is deformed downward, and at this time, the thermosetting adhesive 8 is cured, whereby L1=L2. As a result, parallelism between the bottom surface of the case 4 and the insulating substrate 1 can be maintained, and the insulating substrate 1 and the adhesives (the hot melt adhesive 7 and the thermosetting adhesive 8) are in uniform contact with each other, whereby it is possible to suppress concentration of fastening stress.

As described above, even when there is a variation in the film thickness L1 of the hot melt adhesive 7, the same effect as the case where there is no variation in the film thickness L1 of the hot melt adhesive 7 shown in FIGS. 1 to 4 can be obtained.

### Second Preferred Embodiment

Next, the second preferred embodiment will be described. FIG. 10 is a cross-sectional view illustrating a method of manufacturing the semiconductor device 100 according to a second preferred embodiment of the present disclosure. Note that, in the second preferred embodiment, the same components as those described in the first preferred embodiment are denoted by the same reference numerals, and description thereof is omitted.

Next, in the first preferred embodiment, in the application step, a hot melt adhesive 7 having a film thickness L1 is applied to an upper surface of the peripheral edge portion of the insulating substrate 1, and then a thermosetting adhesive 8 having a film thickness L2 is applied to a periphery of a region to which the hot melt adhesive 7 is applied on the upper surface of the peripheral edge portion of the insulating substrate 1.

On the other hand, in the second preferred embodiment, as shown in FIG. 10, in the application step, the hot melt adhesive 7 having the film thickness L1 is applied to the groove 4a of the case 4, and the thermosetting adhesive 8 having the film thickness L2 to the periphery of a portion corresponding to the region to which the hot melt adhesive 7 is applied on the upper surface of the peripheral edge portion of the insulating substrate 1. Here, the portion corresponding to the region applied with the hot melt adhesive 7 on the upper surface of the peripheral edge portion of the insulating substrate 1 is a portion facing the region applied with the hot melt adhesive 7 on the upper surface of the peripheral edge portion of the insulating substrate 1. Also in the second preferred embodiment, the same effects as those of the first preferred embodiment can be obtained.

### Third Preferred Embodiment

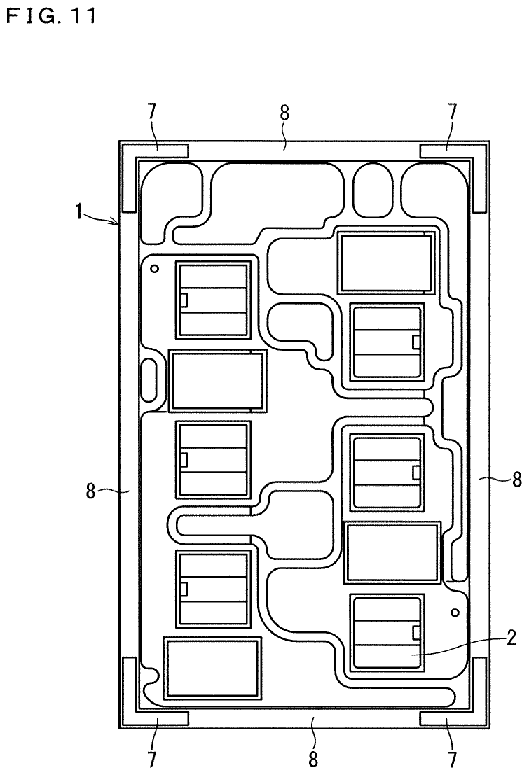

Next, the third preferred embodiment will be described. FIG. 11 is a top view of the insulating substrate 1 after the application step in the third preferred embodiment. Note that, in the third preferred embodiment, the same components as those described in the first and second preferred embodiments are denoted by the same reference numerals, and description thereof is omitted.

As shown in FIG. 11, in the third preferred embodiment, in the application step of the first preferred embodiment, the hot melt adhesive 7 is applied to four corners of the insulating substrate 1 in an L shape in a top view. More specifically, the hot melt adhesive 7 is applied to the portions of the insulating layer 1a at the four corners of the insulating substrate 1. Although not illustrated, in the application step of the second preferred embodiment, the hot melt adhesive 7 is applied to portions in the groove 4a corresponding to four corners of the insulating substrate 1 in an L shape in a bottom view. Here, the positions corresponding to the four corners of the insulating substrate 1 in the groove 4a are positions in the groove 4a facing the four corners of the insulating substrate 1.

As described above, parallelism between the bottom surface of the case 4 and the insulating substrate 1 can be maintained. In addition, by increasing the contact area between the insulating substrate 1 and the hot melt adhesive 7 during the temporary fixing step, concentration of fastening stress can be reduced, and cracking of the insulating substrate 1 can be suppressed.

### Fourth Preferred Embodiment

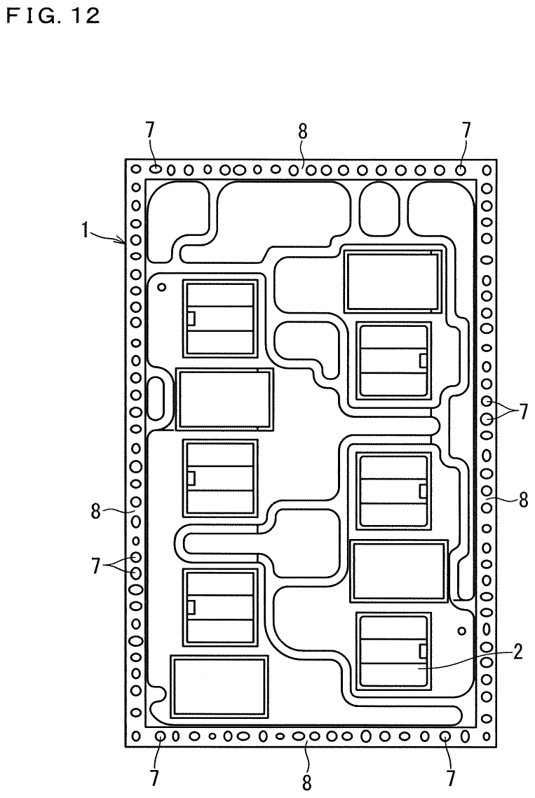

Next, the fourth preferred embodiment will be described. FIG. 12 is a top view of the insulating substrate 1 after the application step in the fourth preferred embodiment. Note that, in the fourth preferred embodiment, the same components as those described in the first to third preferred embodiments are denoted by the same reference numerals, and description thereof is omitted.

As shown in FIG. 12, in the fourth preferred embodiment, in the application step of the first preferred embodiment, the hot melt adhesive 7 is applied along the peripheral edge portion of the insulating substrate 1 in a dotted manner in a top view. Although not illustrated, in the application step of the second preferred embodiment, the hot melt adhesive 7 is applied along the groove 4a in a dotted manner in a bottom view. The hot melt adhesive 7 is applied at substantially equal intervals.

As described above, parallelism between the bottom surface of the case 4 and the insulating substrate 1 can be maintained, and the thicknesses of the adhesives (the hot melt adhesive 7 and the thermosetting adhesive 8) can be secured. In addition, by increasing the contact area between the insulating substrate 1 and the hot melt adhesive 7 during the temporary fixing step, concentration of fastening stress can be reduced, and cracking of the insulating substrate 1 can be suppressed.

### Fifth Preferred Embodiment

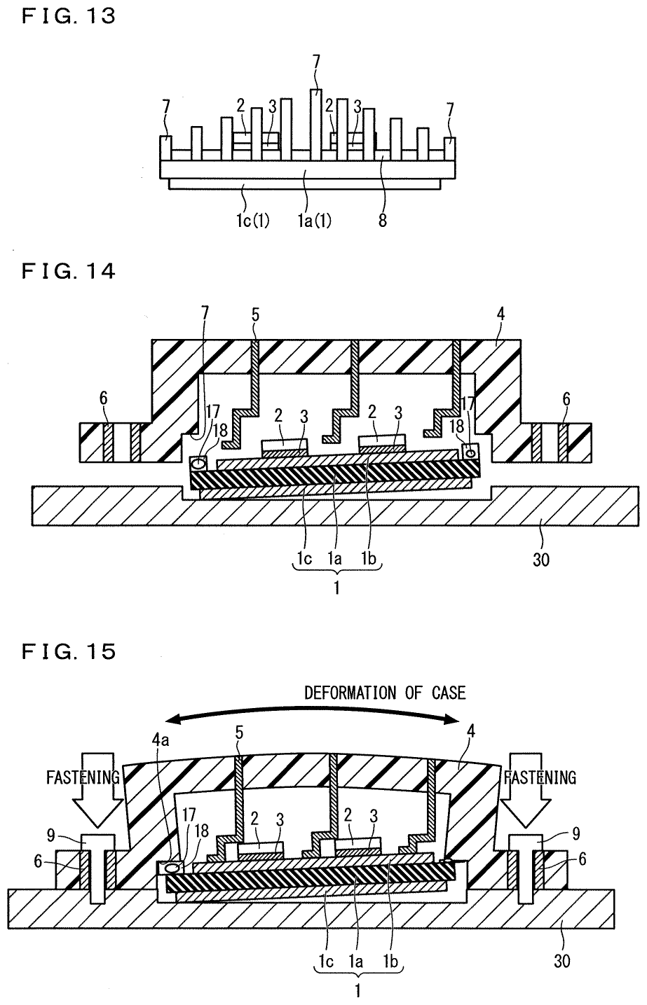

Next, the fifth preferred embodiment will be described. FIG. 13 is a side view of the insulating substrate 1 after the application step in the fifth preferred embodiment. Note that, in the fifth preferred embodiment, the same components as those described in the first to fourth preferred embodiments are denoted by the same reference numerals, and description thereof is omitted.

In a case where the gap between the insulating substrate 1 and the case 4 is not constant, stress is concentrated in a portion of the narrow gap during the temporary fixing step, leading to cracking of the insulating substrate 1. On the other hand, as shown in FIG. 13, in the fifth preferred embodiment, in the application step of the first and second preferred embodiments (more specifically, the fourth preferred embodiment), the film thickness L1 of the hot melt adhesive 7 is set in accordance with the height of the non-constant gap between the insulating substrate 1 and the case 4. As a result, in the temporary fixing step, it is possible to suppress concentration of stress at a narrow gap.

Note that, each preferred embodiment can be freely combined, and each preferred embodiment can be appropriately modified or omitted.

Hereinafter, aspects of the present disclosure will be collectively described as Appendices.

### APPENDIX 1

A method of manufacturing a semiconductor device including an insulating substrate and a case having a groove on a bottom surface fixed to a peripheral edge portion of the insulating substrate, the method comprising:
a placing step of placing the insulating substrate on a case fitting jig;
an application step of applying a hot melt adhesive having a film thickness L1 to an upper surface of the peripheral edge portion of the insulating substrate, and then applying a thermosetting adhesive having a film thickness L2 to a periphery of a region to which the hot melt adhesive is applied on the upper surface of the peripheral edge portion of the insulating substrate;
a temporary fixing step of temporarily fixing the insulating substrate and the case by arranging the case such that the groove is positioned in the peripheral edge portion of the insulating substrate and then fastening the case and the case fitting jig with screws; and a heating step of heating the temporarily fixed insulating substrate and the case to fix the insulating substrate and the case,
wherein L1>L2 in the temporary fixing step, and
L1=L2 in the heating step.

### APPENDIX 2

A method of manufacturing a semiconductor device including an insulating substrate and a case having a groove on a bottom surface fixed to a peripheral edge portion of the insulating substrate, the method comprising:
a placing step of placing the insulating substrate on a case fitting jig;
an application step of applying a hot melt adhesive having a film thickness L1 to the groove of the case, and applying a thermosetting adhesive having a film thickness L2 to a periphery of a portion corresponding to a region to which the hot melt adhesive is applied on the upper surface of the peripheral edge portion of the insulating substrate;
a temporary fixing step of temporarily fixing the insulating substrate and the case by arranging the case such that the groove is positioned in the peripheral edge portion of the insulating substrate and then fastening the case and the case fitting jig with screws; and a heating step of heating the temporarily fixed insulating substrate and the case to fix the insulating substrate and the case,
wherein L1>L2 in the temporary fixing step, and
L1=L2 in the heating step.

### APPENDIX 3

The method of manufacturing a semiconductor device according to Appendix 1, wherein in the application step, the hot melt adhesive is applied to four corners of the insulating substrate in an L shape in a top view.

### APPENDIX 4

The method of manufacturing a semiconductor device according to Appendix 2, wherein in the application step, the hot melt adhesive is applied to portions in the groove corresponding to four corners of the insulating substrate in an L shape in a bottom view.

### APPENDIX 5

The method of manufacturing a semiconductor device according to Appendix 1, wherein in the application step, the hot melt adhesive is applied along the peripheral edge portion of the insulating substrate in a dotted manner in a top view.

### APPENDIX 6

The method of manufacturing a semiconductor device according to Appendix 2, wherein in the application step, the hot melt adhesive is applied along the groove in a dotted manner in a bottom view.

### APPENDIX 7

The method of manufacturing a semiconductor device according to Appendix 1 or 2, wherein in the application step, the film thickness L1 of the hot melt adhesive is set in accordance with a non-constant height of a gap between the insulating substrate and the case.

While the disclosure has been shown and described in detail, the foregoing description is in all aspects illustrative and not restrictive. It is therefore understood that numerous modifications and variations can be devised.

What is claimed is:

1. A method of manufacturing a semiconductor device including an insulating substrate and a case having a groove on a bottom surface fixed to a peripheral edge portion of the insulating substrate, the method comprising:
a placing step of placing the insulating substrate on a case fitting jig;
an application step of applying a hot melt adhesive having a film thickness L1 to an upper surface of the peripheral edge portion of the insulating substrate, and then applying a thermosetting adhesive having a film thickness L2 to a periphery of a region to which the hot melt adhesive is applied on the upper surface of the peripheral edge portion of the insulating substrate;
a temporary fixing step of temporarily fixing the insulating substrate and the case by arranging the case such that the groove is positioned in the peripheral edge portion of the insulating substrate and then fastening the case and the case fitting jig with screws; and
a heating step of heating the temporarily fixed insulating substrate and the case to fix the insulating substrate and the case,
wherein L1>L2 in the temporary fixing step, and
L1=L2 in the heating step.

2. A method of manufacturing a semiconductor device including an insulating substrate and a case having a groove on a bottom surface fixed to a peripheral edge portion of the insulating substrate, the method comprising:
a placing step of placing the insulating substrate on a case fitting jig;
an application step of applying a hot melt adhesive having a film thickness L1 to the groove of the case, and applying a thermosetting adhesive having a film thickness L2 to a periphery of a portion corresponding to a region to which the hot melt adhesive is applied on the upper surface of the peripheral edge portion of the insulating substrate;
a temporary fixing step of temporarily fixing the insulating substrate and the case by arranging the case such that the groove is positioned in the peripheral edge portion of the insulating substrate and then fastening the case and the case fitting jig with screws; and
a heating step of heating the temporarily fixed insulating substrate and the case to fix the insulating substrate and the case,
wherein L1>L2 in the temporary fixing step, and
L1=L2 in the heating step.

3. The method of manufacturing a semiconductor device according to claim 1, wherein in the application step, the hot melt adhesive is applied to four corners of the insulating substrate in an L shape in a top view.

4. The method of manufacturing a semiconductor device according to claim 2, wherein in the application step, the hot melt adhesive is applied to portions in the groove corresponding to four corners of the insulating substrate in an L shape in a bottom view.

5. The method of manufacturing a semiconductor device according to claim 1, wherein in the application step, the hot melt adhesive is applied along the peripheral edge portion of the insulating substrate in a dotted manner in a top view.

6. The method of manufacturing a semiconductor device according to claim 2, wherein in the application step, the hot melt adhesive is applied along the groove in a dotted manner in a bottom view.

7. The method of manufacturing a semiconductor device according to claim 1, wherein in the application step, the film thickness L1 of the hot melt adhesive is set in accordance with a non-constant height of a gap between the insulating substrate and the case.

8. The method of manufacturing a semiconductor device according to claim 2, wherein in the application step, the film thickness L1 of the hot melt adhesive is set in accordance with a non-constant height of a gap between the insulating substrate and the case.
